(19) United States
(12) Patent Application Publication
(10) Pub. No.: US 2025/0112160 A1
(43) Pub. Date: Apr. 3, 2025

(54) INTERLEAVED POWER DELIVERY TO 3D DIE COMPLEXES ABOVE BRIDGE CHIPLET WITHOUT TSV

(71) Applicant: Intel Corporation, Santa Clara, CA (US)

(72) Inventors: Andrew P. COLLINS, Chandler, AZ (US); Jian Yong XIE, Chandler, AZ (US); Aruna KUMAR, Bangalore (IN); Rinkle JAIN, Sherwood, OR (US); Basavaraj KANTHI, Bangalore (IN)

(21) Appl. No.: 18/374,611

(22) Filed: Sep. 28, 2023

(51) Int. Cl. H01L 23/538; H01L 23/00; H01L 23/498; H01L 25/065; H10B 80/00

(52) U.S. Cl. CPC H01L 23/5381; H01L 23/49822; H01L 24/14; H01L 24/16; H01L 25/0652; H10B 80/00; H01L 2224/14151; H01L 2224/16145; H01L 2224/16227; H01L 2224/16238; H01L 2924/1436; H01L 2924/381

(57) ABSTRACT

Embodiments disclosed herein include an apparatus for bump translation. In an embodiment, the apparatus includes a substrate with a first bump field with a first height and a first depth on the substrate, where the first depth is orthogonal to the first height, and where the first bump field further comprises a first pitch in a direction of the first height. In an embodiment, the apparatus includes a second bump field with a second height and a second depth on the substrate, where the second depth is orthogonal to the second height, and where the second bump field comprises a second pitch in a direction of the second height, where the second pitch is smaller than the first pitch. Embodiments include a third bump field with a third height and the second depth, where a sum of the second height and the third height is equal to the first height.

### BACKGROUND

In many three-dimensional (3D) die complexes, a base die is provided and one or more top dies (e.g., chiplets) are provided over the base die. In some instances, the 3D die complex may be communicatively coupled to additional modules, such as a memory module. The connection between the 3D die complex and the additional module is typically made with a bridge die or bridge chiplet. The bridge die can be embedded in the package substrate or within the multi-tiered 3D complex itself. The bridge die is positioned below an edge region of the 3D die complex and for this case does not include a vertical power delivery path (such as a through silicon via (TSV)). This generates problems with power delivery.

The bridge die blocks power delivery paths to the overlying edge region of the 3D die complex. As such, a cantilevered power delivery architecture may be necessary to supply power to the edge region. Cantilevering the power delivery across the top of the bridge die comes with the cost of increased loadline resistance, which negatively impacts available power density within the edge region.

In order to mitigate the power delivery issues, some solutions are to provide low power density circuits in the edge region, or simply provide dummy silicon (i.e., bare silicon without any circuitry) in the edge region. This is less than ideal, especially considering the top die is often fabricated at advanced processing nodes, and it is important to optimize performance by including as many compute cores as possible on the top dies within the base die area.

### BRIEF DESCRIPTION OF THE DRAWINGS

FIG. 1A is a cross-sectional illustration of a portion of an electronic package that includes a first module and a second module coupled together with an embedded bridge, where power delivery is cantilevered across the top of the bridge.

FIG. 1B is a cross-sectional illustration of a portion of an electronic package that includes a first module and a second module coupled together with an embedded bridge that uses one or more redistribution layers, where power delivery is cantilevered across the top of the bridge.

FIG. 1C is a cross-sectional illustration of a portion of an electronic package with an interposer between the package substrate and top dies, in accordance with an embodiment.

FIG. 1D is a cross-sectional illustration of a portion of an electronic package with a bridge that is provided above the package substrate and surrounded by a mold layer, in accordance with an embodiment.

FIG. 2A is a plan view illustration of an electronic package that includes one

or more memory modules and a multi-die module with a base die and one or more top dies, in accordance with an embodiment.

FIG. 2B is a cross-sectional illustration of the electronic package in FIG. 2A that illustrates bridge dies that communicatively couple the memory modules to the multi-die module, in accordance with an embodiment.

FIG. 3A is an illustration of a portion of a bump field that is provided on a bridge, in accordance with an embodiment.

FIG. 3B is an illustration of a portion of a bump field that includes a power delivery region that occupies space freed up by compressing a Y-pitch of the bumps, in accordance with an embodiment.

FIG. 3C is an illustration of a portion of a bump field that includes a wider power delivery region than in FIG. 3B and a Y-pitch that is further compressed, in accordance with an embodiment.

FIG. 4 is a plan view illustration of a bump field that includes a plurality of power delivery regions that are interleaved with the bump fields, in accordance with an embodiment.

FIG. 5A is a plan view illustration of a portion of a bridge that includes a first side with a first bump field with a height, and a second side with a second bump field and a power delivery region that combined have the same height as the first bump field, in accordance with an embodiment.

FIG. 5B is a plan view illustration of a portion of a bridge that includes a first side with a first bump field, and a second side with a second bump field and a power delivery bump field, in accordance with an embodiment.

FIG. 6A is a cross-sectional illustration of a portion of an electronic package that includes a first module coupled to a second module by a bridge, where power is delivered to the second module vertically from the bridge, in accordance with an embodiment.

FIG. 6B is a cross-sectional illustration of a portion of an electronic package that includes a first module coupled to a second module by a bridge with an overlying redistribution layer, where power is delivered to the second module vertically from the bridge, in accordance with an embodiment.

FIG. 7 is a cross-sectional illustration of an electronic system that comprises a first module coupled to a second module through a bridge that includes a first bump field with a first pitch for the first module and a second bump field with a second pitch for the second module, in accordance with an embodiment.

FIG. 8 is a schematic of a computing device built in accordance with an embodiment.

### EMBODIMENTS OF THE PRESENT DISCLOSURE

Described herein are electronic systems, and more particularly, three-dimensional (3D) die complexes with improved power delivery above bridge chiplets, in accordance with various embodiments. In the following description, various aspects of the illustrative implementations will be described using terms commonly employed by those skilled in the art to convey the substance of their work to others skilled in the art. However, it will be apparent to those skilled in the art that the present disclosure may be practiced with only some of the described aspects. For purposes of explanation, specific numbers, materials and configurations are set forth in order to provide a thorough understanding of the illustrative implementations. However, it will be apparent to one skilled in the art that the present disclosure may be practiced without the specific details. In other instances, well-known features are omitted or simplified in order not to obscure the illustrative implementations.

Various operations will be described as multiple discrete operations, in turn, in a manner that is most helpful in understanding the present disclosure, however, the order of description should not be construed to imply that these operations are necessarily order dependent. In particular, these operations need not be performed in the order of presentation.

As noted above, the integration of multiple dies and modules (e.g., three-dimensional (3D) die complexes and memory modules) comes with significant integration challenges. One particularly important challenge is the ability to provide power to edge regions of the top dies of a 3D die complex. More specifically, an underlying bridge die that couples the 3D die complex to the memory module blocks access to vertical power delivery. As such, cantilevered power (which increases loadline resistance), dummy silicon, or expensive through silicon via (TSV) architectures are needed for power delivery accommodation.

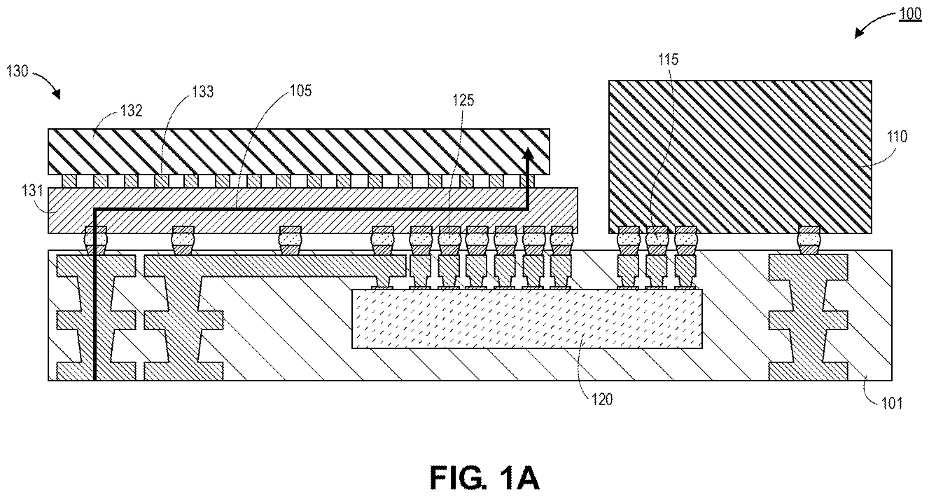

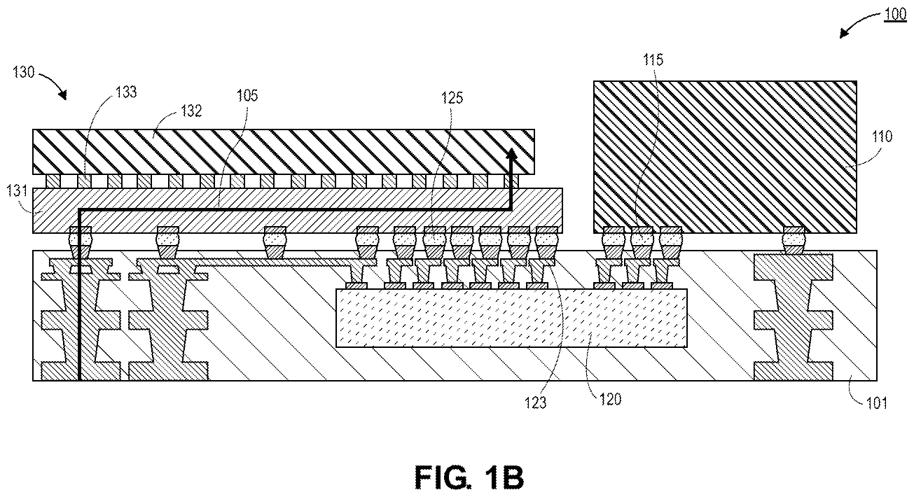

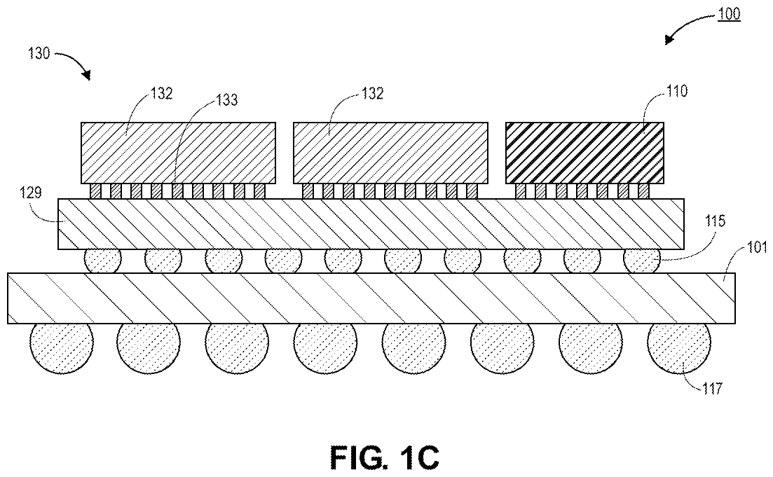

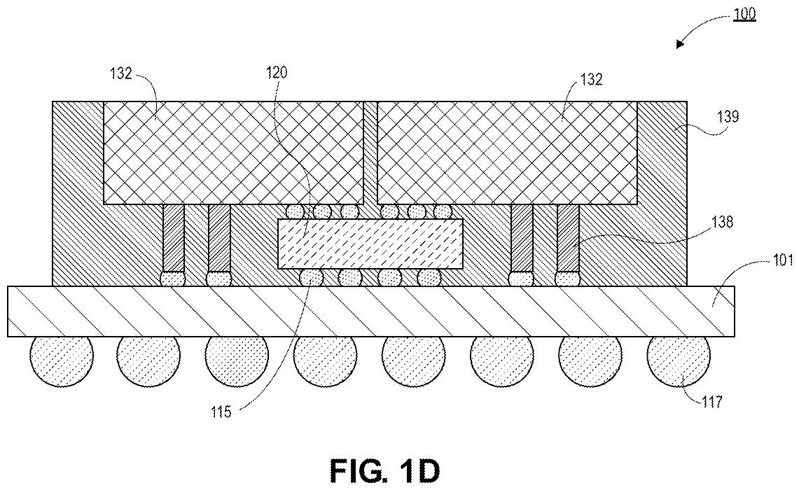

An example of such a power delivery issue is shown in FIG. 1A. FIG. 1A illustrates an electronic package 100. The electronic package 100 may comprise a package substrate 101. The package substrate 101 may be an organic package substrate. The package substrate 101 may include a core (not shown) in some instances. As shown, a first module 110 and a second module 130 are coupled to the package substrate 101.

The first module 110 may include a memory module such as a high bandwidth memory (HBM) module. The second module 130 may be a 3D die complex. For example, the second module 130 may include a base die 131 and one or more overlying top dies 132. The top dies 132 may be compute chiplets with processing cores and related circuitry. The top die 132 may be coupled to the base die 131 with interconnects 133, such as copper bumps, solder, hybrid bonding interconnects (HBI), or the like.

The first module 110 may be communicatively coupled to the second module 130 by a die 120, such as a bridge die 120. The die 120 may include high density routing in order to provide high bandwidth signal transmission between the first module 110 and the second module 130. The die 120 may be embedded in the package substrate 101. Though, other architectures may include a bridge die 120 that is provided above the package substrate 101. The die 120 may be coupled to the first module 110 and the second module 130 through interconnects that may include solder interconnects 115 and 125, respectively.

The die 120 may be provided under an edge region of the second module 130. Since the die 120 is present below the edge region of the second module 130, there is no vertical access for power to reach the top die 132. Accordingly, a power delivery path 105 must start outside of the die 120 and cantilever over the die 120 before being routed up into the top die 132. This cantilevering results in a significant loadline resistance increase along the power delivery path 105. As such, the power density of the edge region of the second module 130 must be decreased. In some instances, a dummy silicon piece may replace the top die 132 in the edge region.

It is to be appreciated that such power delivery issues arise with many different bridge die architectures. For example, an alternative architecture is shown in FIG. 1B. The electronic package 100 in FIG. 1B may be substantially similar to the electronic package 100 in FIG. 1A, with the exception of the architecture of the bridge 120. Instead of having direct vertical connections to the interconnects 115 and 125, the bridge 120 in FIG. 1B may include one or more redistribution layers 123. For example, a single redistribution layer 123 is shown in FIG. 1B. The redistribution layer 123 may allow for pitch translation or the like between the die 120 and the overlying modules 110 and 130.

Additional 3D packaging architectures may also suffer from power delivery issues similar to those described above. For example, FIG. 1C is another example of an electronic package 100. In FIG. 1C, the package substrate 101 with underlying bumps 117 may support an interposer 129. The interposer 129 may be a redistribution layer (RDL) interposer 129. That is, redistribution lines (e.g., copper lines, vias, etc.) (which are not shown for simplicity) may be embedded in the interposer 129. The redistribution lines may provide electrical connections between the first module 110 and the second module 130. The interposer 129 may be an organic based material, a silicon based material, or the like. Similar power delivery issues arise from this configuration as well. That is, power to the edge of dies 132 may require cantilevering.

Another example of a problematic 3D integration solution is shown in FIG. 1D. In FIG. 1D, the bridge die 120 is provided over a top surface of the substrate 101. Copper pillars 138 connect the top dies 132 to the package substrate 101. A mold layer 139 surrounds the bridge die 120, the copper pillars 138, and the top dies 132. Due to the presence of the bridge die 120, power delivery to the edges of the top dies 132 is limited. As such, cantilevered power delivery paths are also needed for this architecture.

It is to be appreciated that simplified architectures of the interconnects between the modules 110 and 130 and the package substrate 101, and between the modules 110 and 130 and the die 120 are shown for ease of illustration and improved understand of aspects disclosed herein. In reality, additional layers (e.g., solder resists, redistribution layers, barrier layers, etc.) may be include in the interconnect architectures between components described herein. Further, while certain architectures are shown in FIGS. 1A-1D, it is to be appreciated that many different 3D packaging architectures exist, and these additional architectures may also be limited by power deliver issues similar to those described herein. Accordingly, embodiments disclosed herein should not be interpreted as being limited to any of the specific 3D architectures explicitly described herein.

In view of the issues with power delivery described above, embodiments disclosed herein include improved bridge die architectures. In some embodiments, a power delivery region is interleaved among a bump field that connects to the second module. The power delivery region may include one or more rows of bumps dedicated to power delivery in order to provide vertical power paths to the edge region of the overlying second module. As such, power density can be improved and a number of compute cores in the top die can be optimized.

However, it is to be appreciated that simply adding an extra row of power delivery bumps is not without issue. Particularly, the bump field under the first module may have a preset bump field shoreline height. For reduction in assembly complexity, the bump field shoreline of the bump field under the second module should match the bump field shoreline height of the bump field under the first module.

Accordingly, embodiments include a bridge die with a first side (under the first module) and a second side (under the second module). The first side includes a bump field with a standard shoreline height. This is enabled by spacing the bumps with a first Y-pitch. The second side includes a bump field with a reduced shoreline height enabled by spacing the bumps with a second (smaller) Y-pitch. The second side also includes a power deliver region running perpendicular to the bump field shoreline. The combined shoreline height of the bump field on the second side and the height of the power delivery region equals the height of the bump field shoreline on the first side.

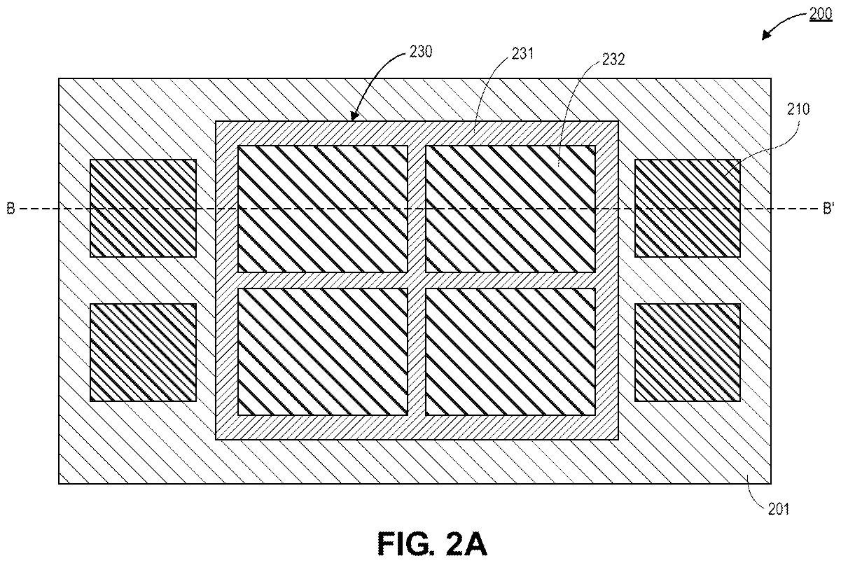

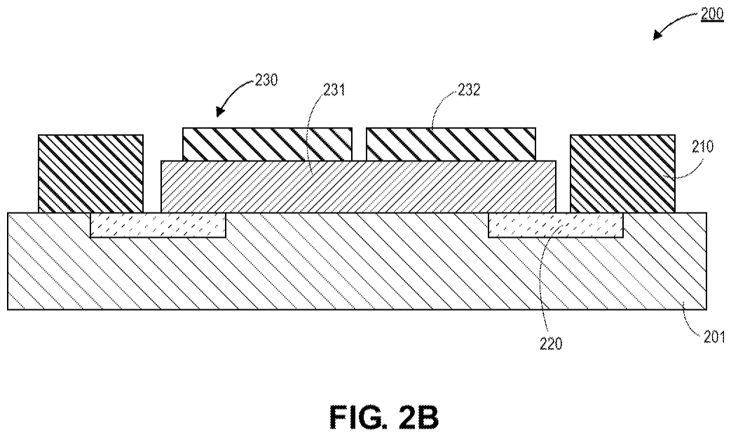

Referring now to FIG. 2A, a plan view illustration of an electronic package 200 is shown, in accordance with an embodiment. The electronic package 200 may comprise a package substrate 201. The package substrate 201 may be an organic package substrate. For example, the package substrate 201 may include laminated layers of buildup film or the like. The package substrate 201 may include a core (e.g., an organic core, a glass core, etc.).

In an embodiment, one or more first modules 210 are provided over the package substrate 201. The first module 210 may comprise a memory device. For example, the first module 210 may include a stack of two or more memory dies, such as an HBM module. While embodiments disclosed herein often refer to the first module 210 as a memory device, it is to be appreciated that embodiments are not limited to such structures. For example, the first module 210 may be another compute die or another 3D die complex.

In an embodiment a second module 230 is provided over the package substrate 201. The second module 230 may be adjacent to one or more of the first modules 210. In a particular embodiment, the second module 230 may comprise a 3D die complex. For example, the second module 230 may include a base die 231 with one or more overlying top dies 232. The base die 231 and the top dies 232 may be fabricated at different processing nodes, with the top dies 232 being at a more advanced process node. The top dies 232 may include compute functionality, such as compute cores, graphics cores, or the like.

The top dies 232 may sometimes be referred to as chiplets or tiles. The top dies 232 may be communicatively coupled to each other (or stitched together) through the base die 231. The smaller top dies 232 can be fabricated at advanced processing nodes with higher yields compared to a single large die. As such, improved computing power can be provided without sacrificing yield when a 3D die complex is used.

Referring now to FIG. 2B, a cross-sectional illustration of the electronic package 200 in FIG. 2A along line B-B′ is shown, in accordance with an embodiment. In the illustrated embodiment, the interconnects between components are omitted for simplicity, and in order to more clearly depicts aspects of certain embodiments. However, it is to be appreciated that interconnects such as solder, copper bumps, HBIs, etc. may be provided in the electronic package 200. FIG. 2B is used to demonstrate relative positioning of components with respect to each other and any interconnect architectures can be used.

In an embodiment, the electronic package 200 may include dies 220 that are embedded in the package substrate 201. The dies 220 may be bridge dies 220 (sometimes referred to as bridge chiplets). While shown as being embedded in the package substrate 201, the die 220 may also be provided above the package substrate 201 in some packaging architectures. Regardless of location, the die 220 may include bumping solutions similar to those described in greater below. The die 220 may comprise silicon or other semiconductor materials. The die 220 may also be a glass die 220 in other embodiments.

In an embodiment, the die 220 may provide coupling between the first module 210 and the second module 230. The coupling may be considered electrical coupling, communicative coupling, or the like. More generally, the die 220 includes high density routing (e.g., traces, pads, etc.) that provide a path to propagate signals between the first module 210 and the second module 230.

As shown, the die 220 is provided below an edge region of the second module 230, which includes an edge region of the base die 231 and an edge region of the overlying top die 232. Accordingly, power delivery vertically to the edge region is blocked by the die 220. That is, power originating from the package substrate 201 does not have a path vertically through the die 220 to reach the edge region of the second module 230.

Therefore, embodiments disclosed herein include a die 220 that includes an integrated power delivery lane. Further, embodiments allow for the inclusion of a power delivery lane without increasing total bump field height along the die 220 edge. This ensures simple integration with the bump field under the first die module 210, as will be described below. The additional space for the power delivery lane is provided by shrinking a Y-pitch within the bump field below the second module 230.

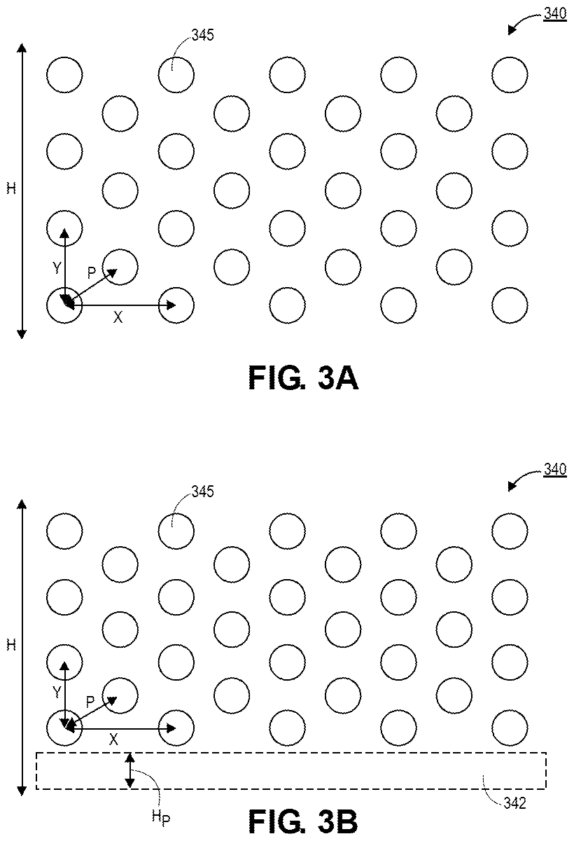

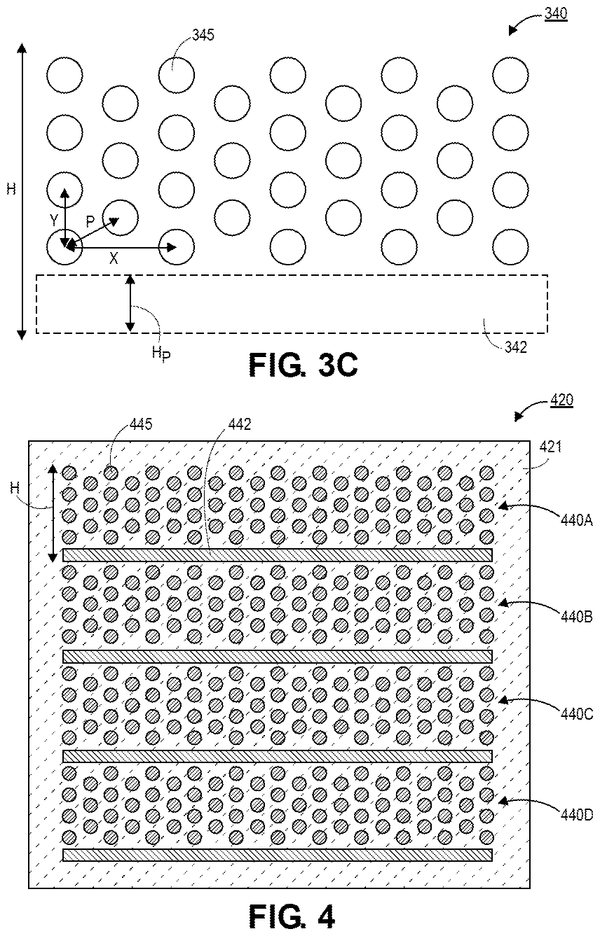

Referring now to FIG. 3A, a schematic of a bump field 340 on a bridge die is shown, in accordance with an embodiment. The bump field 340 may comprise a plurality of bump pads 345 that are arranged across a surface of the bridge die. The bump pads 345 may be arranged in a hexagonal packing pattern. That is, each row is offset from the neighboring rows by half the pitch of the bump pads 345. The bump pads 345 may have a Y-pitch (Y) and an X-pitch (X). A diagonal pitch (P) may also be provided. The diagonal pitch P may be smaller than the Y-pitch and the X-pitch. Though, in a hexagonal packing pattern P=X or P=Y. In some instances the diagonal pitch P is the minimum pitch achievable by the processing used to form the bridge die, or the minimum pitch achievable by the overlying modules (e.g., first module 210 or second module 230 in FIGS. 2A and 2B).

In an embodiment, the bump field 340 may have a height H along a die edge of the bridge die. The height H may sometimes be referred to as a shoreline height. The height H may be set by standards or other design parameters. For example, in the case of a HBM first module, the bump field 340 may be a DWORD bump field. In HBM3 standards, the height H may be approximately 385 μm. Though, larger or smaller heights H may be used in some embodiments. While referred to as “height”, it is to be appreciated that the height H is not in the thickness direction (i.e., the Z-height). Instead, the height H is in a direction that is substantially parallel to a major direction of the die edge.

In the case of an HBM3 application, the Y-pitch may be approximately 110 μm and the X-pitch may be approximately 96 μm. This provides a diagonal pitch P of approximately 73 μm. While four rows of bump pads 345 are shown at the edge of the bump field 340, it is to be appreciated that each DWORD comprises 3.5 bump pads 345. That is, the fourth bump pad 345 is shared with a neighboring DWORD bump field 340. As such, the total height H (385 μm) is equal to 110 μm*3.5=385 μm. While a specific example of the HBM3 standard layout is provided, it is to be appreciated that embodiments may scale to other standards (e.g., HBM4 or beyond), or the layout may conform to other standards. More generally, the bump field 340 may have any pitches (i.e., Y-pitch, X-pitch, or diagonal pitch P) and/or any height H.

The bump field 340 in FIG. 3A is an example of a bump field under the first module. That is, the bump field 340 is on a first side of the bridge die. The second side of the bridge die includes a bump field 340 under the second module. This bump field 340 may be augmented by the inclusion of a power delivery region. The power delivery region provides vertical access to provide power directly to the edge region of the second module. However, in order to simplify assembly and manufacturing, the combined height H of the bump field 340 on the second side of the bridge die and the power delivery region should match the height H of the bump field 340 on the first side of the bridge die.

Referring now to FIG. 3B, a schematic of a bump field 340 for servicing the second module is shown, in accordance with an embodiment. In an embodiment, the bump field 340 may maintain bump pads 345 that have the same dimensions as the bump pads 345 in FIG. 3A. Additionally, the X-pitch (X) may be the same as the X-pitch in FIG. 3A. However, in order to conserve space, the Y-pitch (Y) is reduced compared to the Y-pitch in FIG. 3A. This also reduces the diagonal pitch P. Though, in other embodiments, the X-pitch (X) in FIG. 3B may be made smaller, larger, or the same size as the X-pitch (X) in FIG. 3A.

In an embodiment, the space saved by the reduction of the Y-pitch is used by the inclusion of a power delivery region 342. The power delivery region 342 may include a height H_{P}. The height H_{P} plus the height of the bump field 340 may be equal to the height H that was set by the bump field 340 in FIG. 3A. The power delivery region 342 may extend in a direction perpendicular to the edge of the die (i.e., in the X-direction). The depth of the power delivery region 342 may be substantially similar to the depth of the bump field 340. The power delivery region 342 may include bump pads (not shown) that are configured to be coupled to a power source.

In one instance, the Y-pitch may be reduced to approximately 96.25 μm (though a perfect hexagonal compression is typically 95.26 μm). This provides a total height of the bump field 340 that is approximately 336.875 μm (i.e., 96.25 μm*3.5). With a height H of 385 uμm, this allows for a height H_{P} of the power delivery region 342 to be approximately 48.125 μm. In an embodiment, the bump pitches of power delivery bumps may be different than those of the bump field 340.

Referring now to FIG. 3C, a schematic of a bump field 340 is provided in accordance with yet another additional embodiment. The bump field 340 in FIG. 3C is similar to that of FIG. 3B, with a more aggressive scaling in order to provide even more room for the power delivery region 342. For example, the Y-pitch (Y) may further be reduced to approximately 77 μm. As such, the height of the bump field may be approximately 269.5 μm (i.e., 77 μm*3.5). For a height H of approximately 385 μm, this leaves 115.5 μm for the height H_{P} of the power delivery region 342. Increasing the height H_{P} of the power delivery region 342 may allow for more than one row of power delivery bumps. As such, power density to the overlying second module may be increased.

Referring now to FIG. 4, a plan view illustration of a portion of a die 420 is shown, in accordance with an embodiment. In an embodiment, the portion of the die 420 shown is on the side of the second module. The side of the die 420 under the first module is omitted for clarity. The die 420 may comprise a substrate 421, such as a silicon substrate or the like. In an embodiment, a plurality of bump fields 440A-440D with bump pads 445 are provided adjacent to each other along the die edge.

In an embodiment, a plurality of power delivery regions 442 may be interleaved with the bump fields 440A-440D. The power delivery regions 442 may extend in a direction perpendicular to the edge of the substrate 421. In an embodiment, the combination of the height of an individual bump field 440 with an adjacent power delivery region 442 may be equal to the height H. The height H may be the same height as is used on the opposite side of the die 420 under the first module.

In an embodiment, each bump field 440A-440D may correspond to a DWORD region of a link between a 3D die complex and a HBM module. In a particular embodiment, the height H may be approximately 385 μm. Though, larger or smaller heights H may be used in other embodiments in order to match the localized AWORD/DWORD heights or total height H set by the HBM side of the die 420. In an embodiment, the power delivery regions 442 may comprise power delivery bump pads (not shown).

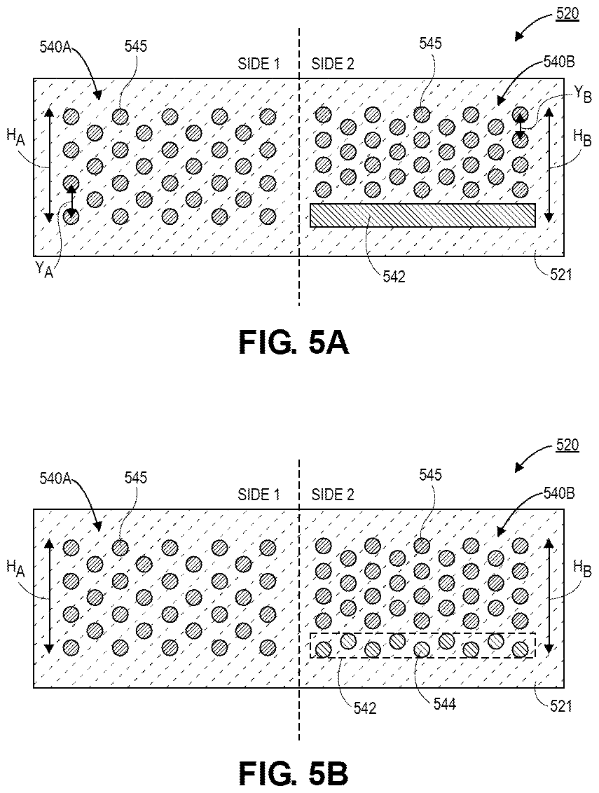

Referring now to FIG. 5A, a plan view illustration of a portion of a die 520 is shown, in accordance with an embodiment. The die 520 may include a substrate 521, such as a silicon substrate or the like. The die 520 comprises a first side (Side 1) and a second side (Side 2). The first side may be provided under a first module, such as an HBM module, and the second side may be provided under a second module, such as a 3D die complex. In an embodiment, a first bump field 540A with bump pads 545 is provided on the first side, and a second bump field 540B with bumps pads 545 is provided on the second side.

In an embodiment, the first bump field 540A may have a height H_{A} and a Y-pitch (Y_{A}). In an embodiment, the second bump field 540B may have a Y-pitch (Y_{B}) that is smaller than the Y-pitch (Y_{A}). The compressed second bump field 540B provides room for the power delivery region 542. The combined height of the second bump field 540B and the power delivery region 542 may be height H_{B}. In an embodiment, height H_{B} is substantially equal to height H_{A}. For example, the heights H_{A} and H_{B} may be approximately 385 μm.

In an embodiment, the X-pitch of the first bump field 540A and the second bump field 540B are substantially equal to each other. As such, depths into the die 520 of each bump field 540A and 540B are substantially equal to each other. In other embodiments, X-pitches may be different between the bump fields 540A and 540B. For example, the X-pitch of second bump field 540B may be smaller than the X-pitch of the first bump field 540A. As such, the second bump field 540B may have a depth into the die 520 that is smaller than a depth into the die 520 of the first bump field 540A. In an embodiment, the depth of the power delivery region 542 may be substantially equal to the depth of the second bump field 540B.

Referring now to FIG. 5B, a plan view illustration of a portion of a die 520 is shown, in accordance with an additional embodiment. The die 520 in FIG. 5B may be substantially similar to the die 520 in FIG. 5A, with the exception of the illustration of power delivery bump pads 544 within the power delivery region 542. The power delivery bump pads 544 may have pitches (e.g., X-pitch, Y-pitch, diagonal pitch) that is substantially similar to those in the second bump field 540B. In other embodiments, the pitches of the power delivery bump pads 544 may be different than those in the second bump field 540B.

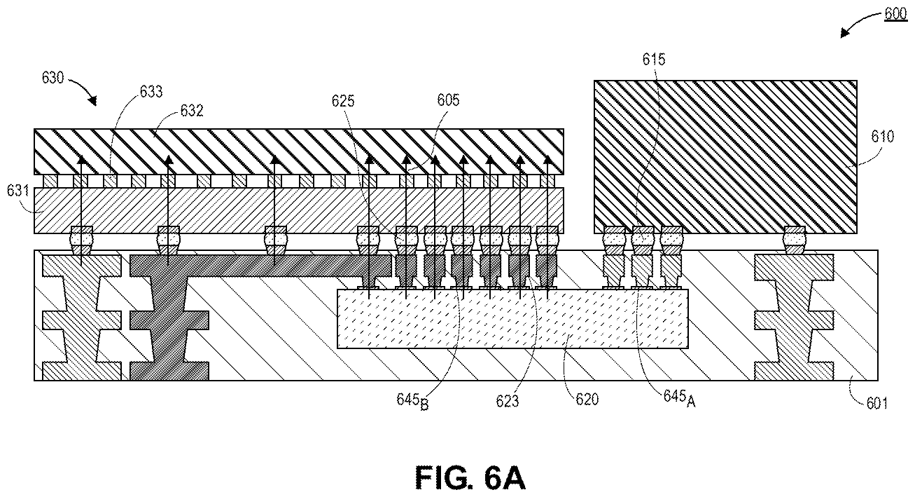

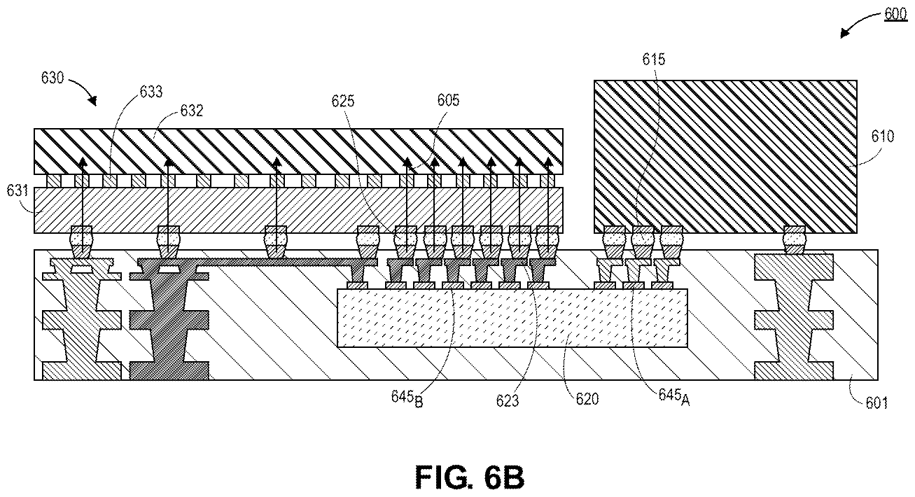

Referring now to FIG. 6A, a cross-sectional illustration of a portion of an electronic package 600 is shown, in accordance with an embodiment. The electronic package 600 may comprise a package substrate 601. In an embodiment, a first module 610 and a second module 630 are coupled to the package substrate 601 (e.g., through interconnect 615 and 625, respectively). The first module 610 may comprise an HBM module in some instances. The second module 630 may comprise a 3D die complex with a base die 631 and one or more top dies 632. The top die 632 may be coupled to the base die 631 by interconnects 633.

In an embodiment, the first module 610 is communicatively coupled to the second module 630 through a die 620, such as a bridge die 620. The die 620 may include a first side under the first module 610 and a second side under the second module 630. The first side may include bump pads 645A and the second side may include bump pads 645B. In an embodiment, the Y-pitch (into and out of the plane of FIG. 6A) is compressed in order to allow for the inclusion of a power delivery region, which is shown in the plane of FIG. 6A. As shown, power delivery paths 605 extend up from the power delivery region vertically through interconnects 625 into the edge region of the second module 630. As such, the entire footprint of the top die 632 can be used for high power density circuitry, such as compute cores or graphics cores. Further, since there is no need to cantilever the power across the die 620 the loadline resistance is significantly improved, and higher performance is enabled.

Referring now to FIG. 6B, a cross-sectional illustration of an electronic package 600 is shown, in accordance with an additional embodiment. The electronic package 600 in FIG. 6B may be similar to the electronic package 600 in FIG. 6A, with the exception of the connection to the die 620. Instead of having a direct vertical connection between bump pads 645B and the interconnects 625, one or more redistribution layers 623 may be provided. The redistribution layers 623 may provide pitch translation or the like.

While an example of two different die 620 architectures are shown in FIGS. 6A and 6B, it is to be appreciated that many different bridge die architectures may embody a bump field that is coupled with a power delivery region, while still matching the height set by the first module 610. For example, some embodiments may include a die 620 that is provided above the package substrate 601 instead of being embedded in the package substrate 601. Further, in some embodiments the die 620 may include TSVs to further enhance power delivery. More particularly, embodiments disclosed herein may include a bump field that is coupled with a power delivery region, while still matching the height set by the first module 610 using any 3D packaging architecture, such as those also described above with respect to FIG. 1C and FIG. 1D.

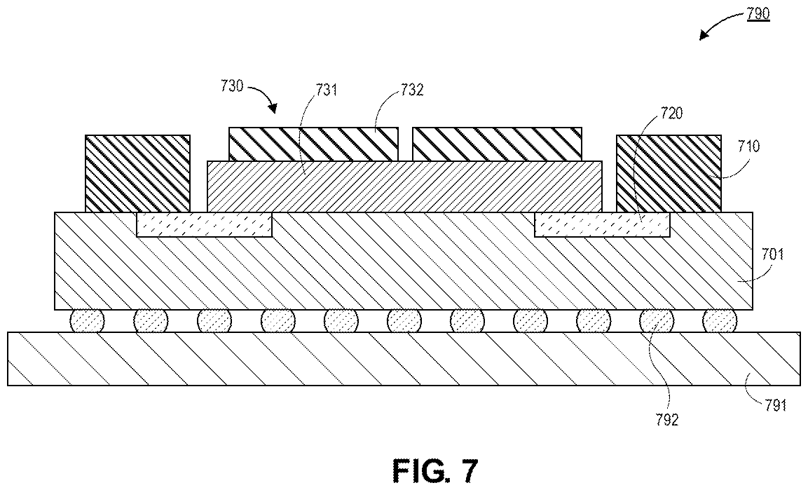

Referring now to FIG. 7, a cross-sectional illustration of an electronic system 790 is shown, in accordance with an embodiment. The electronic system 790 may comprise a board 791, such as a printed circuit board (PCB). The board 791 may be coupled to the package substrate 701 through interconnects 792. The interconnects 792 may be solder balls, sockets, or the like.

In an embodiment, a first module 710 and a second module 730 are coupled to the package substrate 701. The first module 710 may be an HBM module, and the second module 730 may be a 3D die complex including a base die 731 and top dies 732. Dies 720, such as bridge dies 720, may communicatively couple the first module 710 to the second module 730. In the illustrated embodiment, the first module 710, the second module 730, and the die 720 are shown as being directly on each other. However, it is to be appreciated that interconnects (e.g., solder balls, copper bumps, etc.) may be provided between components, similar to embodiments described in greater detail above.

In an embodiment, the die 720 may include a first side under the first module 710 and a second side under the second module 730. A first bump field on the first side may have a first height with bump pads having a first Y-pitch. A second bump field on the second side may be adjacent to a power delivery region. The combined height of the second bump field and the power delivery region may be equal to the first height. In order to provide space savings, the second bump field may have a second Y-pitch that is smaller than the first Y-pitch.

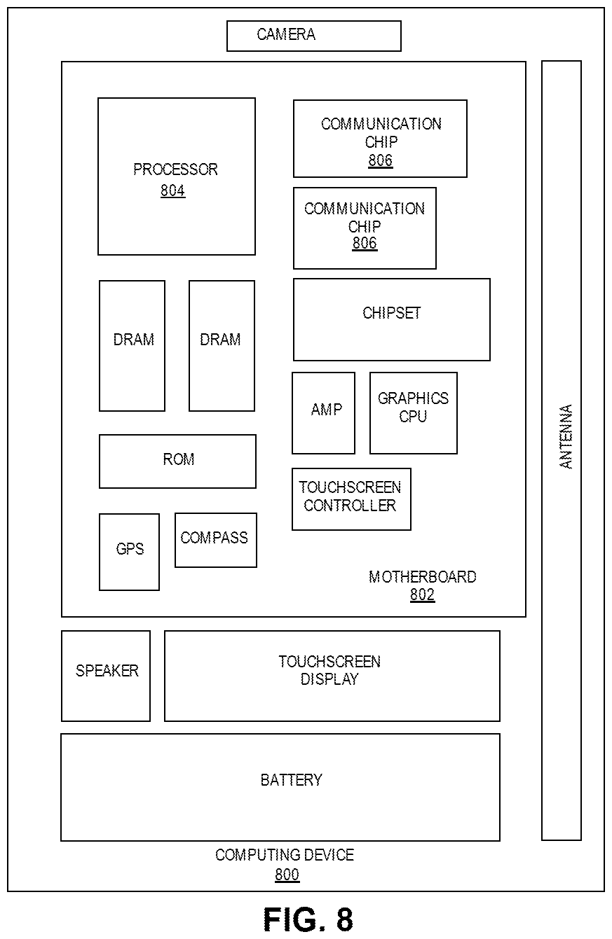

FIG. 8 illustrates a computing device 800 in accordance with one implementation of the disclosure. The computing device 800 houses a board 802. The board 802 may include a number of components, including but not limited to a processor 804 and at least one communication chip 806. The processor 804 is physically and electrically coupled to the board 802. In some implementations the at least one communication chip 806 is also physically and electrically coupled to the board 802. In further implementations, the communication chip 806 is part of the processor 804.

These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 806 enables wireless communications for the transfer of data to and from the computing device 800. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 806 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 800 may include a plurality of communication chips 806. For instance, a first communication chip 806 may be dedicated to shorter range wireless communications such as Wi-Fi and Bluetooth and a second communication chip 806 may be dedicated to longer range wireless communications such as GPS, EDGE, GPRS, CDMA, WiMAX, LTE, Ev-DO, and others.

The processor 804 of the computing device 800 includes an integrated circuit die packaged within the processor 804. In some implementations of the disclosure, the integrated circuit die of the processor may be part of an electronic package that includes a bridge die that includes a first bump field with a first Y-pitch, and a second bump field with a second Y-pitch that is adjacent to a power delivery region, in accordance with embodiments described herein. The term “processor” may refer to any device or portion of a device that processes electronic data from registers and/or memory to transform that electronic data into other electronic data that may be stored in registers and/or memory.

The communication chip 806 also includes an integrated circuit die packaged within the communication chip 806. In accordance with another implementation of the disclosure, the integrated circuit die of the communication chip may be part of an electronic package that includes a bridge die that includes a first bump field with a first Y-pitch, and a second bump field with a second Y-pitch that is adjacent to a power delivery region, in accordance with embodiments described herein.

In an embodiment, the computing device 800 may be part of any apparatus. For example, the computing device may be part of a personal computer, a server, a mobile device, a tablet, an automobile, or the like. That is, the computing device 800 is not limited to being used for any particular type of system, and the computing device 800 may be included in any apparatus that may benefit from computing functionality.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize.

These modifications may be made to the disclosure in light of the above detailed description. The terms used in the following claims should not be construed to limit the disclosure to the specific implementations disclosed in the specification and the claims. Rather, the scope of the disclosure is to be determined entirely by the following claims, which are to be construed in accordance with established doctrines of claim interpretation.

Example 1: an apparatus, comprising: a substrate; a first bump field with a first height and a first depth on the substrate, wherein the first depth is orthogonal to the first height, and wherein the first bump field further comprises a first pitch in a direction of the first height; a second bump field with a second height and a second depth on the substrate, wherein the second depth is orthogonal to the second height, and wherein the second bump field comprises a second pitch in a direction of the second height, wherein the second pitch is smaller than the first pitch; and a third bump field with a third height and the second depth, wherein a sum of the second height and the third height is equal to the first height.

Example 2: the apparatus of Example 1, wherein the first bump field has a first number of first rows, and wherein the second bump field has a second number of second rows, wherein the first number is equal to the second number.

Example 3: the apparatus of Example 1 or Example 2, wherein the third bump field comprises power delivery bump pads.

Example 4: the apparatus of Examples 1-3, wherein the first depth is different than the second depth.

Example 5: the apparatus of Examples 1-3, wherein the first depth is equal to the second depth.

Example 6: the apparatus of Examples 1-5, wherein the first height is approximately 385 μm or less.

Example 7: the apparatus of Example 6, wherein the first pitch is approximately 110 μm or less, and wherein the second pitch is approximately 96 μm or less.

Example 8: the apparatus of Examples 1-7, further comprising: a first module coupled to the first bump field; and a second module coupled to the second bump field and the third bump field, wherein the apparatus communicatively couples the first module to the second module.

Example 9: the apparatus of Example 8, wherein the first module is a memory, and wherein the second module is a multi-die module with a base die and one or more overlying top dies.

Example 10: the apparatus of Example 8 or Example 9, wherein the apparatus is embedded in a package substrate or is provided over a package substrate.

Example 11: an apparatus, comprising: a substrate; a first bump field on the substrate; a second bump field on the substrate; and a plurality of electrically conductive lanes interleaved with the second bump field.

Example 12: the apparatus of Example 11, wherein the first bump field has a height, and wherein the second bump field, including the electrically conductive lanes has the height.

Example 13: the apparatus of Example 11 or Example 12, wherein the plurality of electrically conductive lanes comprises a plurality of bump pads.

Example 14: the apparatus of Examples 11-13, wherein each electrically conductive lane has a height that is approximately 115 μm or less.

Example 15: the apparatus of Examples 11-14, wherein the first bump field comprises first bump pads with a first pitch, and wherein the second bump field comprises second bump pads with a second pitch that is smaller than the first pitch.

Example 16: the apparatus of Examples 11-15, further comprising: a first module coupled to the first bump field; and a second module coupled to the second bump field, wherein the substrate communicatively couples the first module to the second module.

Example 17: the apparatus of Example 16, wherein the first module comprises a memory, and wherein the second module comprises a base die with one or more overlying top dies.

Example 18: an apparatus, comprising: a board; a package substrate coupled to the board; a first module coupled to the package substrate; a second module coupled to the package substrate; and a bridge to communicatively couple the first module to the second module, wherein the bridge comprises: a first bump field with a first pitch coupled to the first module; a second bump field with a second pitch coupled to the second module; and a plurality of power delivery fields interleaved with the second bump field.

Example 19: the apparatus of Example 18, wherein the plurality of power delivery fields are configured to provide power to an edge region of the second module.

Example 20: the apparatus of Example 18 or Example 19, wherein the apparatus is part of a personal computer, a server, a mobile device, a tablet, or an automobile.

What is claimed is:

1. An apparatus, comprising:
a substrate;
a first bump field with a first height and a first depth on the substrate, wherein the first depth is orthogonal to the first height, and wherein the first bump field further comprises a first pitch in a direction of the first height;
a second bump field with a second height and a second depth on the substrate, wherein the second depth is orthogonal to the second height, and wherein the second bump field comprises a second pitch in a direction of the second height, wherein the second pitch is smaller than the first pitch; and
a third bump field with a third height and the second depth, wherein a sum of the second height and the third height is equal to the first height.

2. The apparatus of claim 1, wherein the first bump field has a first number of first rows, and wherein the second bump field has a second number of second rows, wherein the first number is equal to the second number.

3. The apparatus of claim 1, wherein the third bump field comprises power delivery bump pads.

4. The apparatus of claim 1, wherein the first depth is different than the second depth.

5. The apparatus of claim 1, wherein the first depth is equal to the second depth.

6. The apparatus of claim 1, wherein the first height is approximately 385 μm or less.

7. The apparatus of claim 6, wherein the first pitch is approximately 110 μm or less, and wherein the second pitch is approximately 96 μm or less.

8. The apparatus of claim 1, further comprising:
a first module coupled to the first bump field; and
a second module coupled to the second bump field and the third bump field, wherein the apparatus communicatively couples the first module to the second module.

9. The apparatus of claim 8, wherein the first module is a memory, and wherein the second module is a multi-die module with a base die and one or more overlying top dies.

10. The apparatus of claim 8, wherein the apparatus is embedded in a package substrate or is provided over a package substrate.

11. An apparatus, comprising:
a substrate;
a first bump field on the substrate;
a second bump field on the substrate; and
a plurality of electrically conductive lanes interleaved with the second bump field.

12. The apparatus of claim 11, wherein the first bump field has a height, and wherein the second bump field, including the electrically conductive lanes has the height.

13. The apparatus of claim 11, wherein the plurality of electrically conductive lanes comprises a plurality of bump pads.

14. The apparatus of claim 11, wherein each electrically conductive lane has a height that is approximately 115 μm or less.

15. The apparatus of claim 11, wherein the first bump field comprises first bump pads with a first pitch, and wherein the second bump field comprises second bump pads with a second pitch that is smaller than the first pitch.

16. The apparatus of claim 11, further comprising:
a first module coupled to the first bump field; and
a second module coupled to the second bump field, wherein the substrate communicatively couples the first module to the second module.

17. The apparatus of claim 16, wherein the first module comprises a memory, and wherein the second module comprises a base die with one or more overlying top dies.

18. An apparatus, comprising:
a board;
a package substrate coupled to the board;
a first module coupled to the package substrate;
a second module coupled to the package substrate; and
a bridge to communicatively couple the first module to the second module, wherein the bridge comprises:
a first bump field with a first pitch coupled to the first module;
a second bump field with a second pitch coupled to the second module; and
a plurality of power delivery fields interleaved with the second bump field.

19. The apparatus of claim 18, wherein the plurality of power delivery fields are configured to provide power to an edge region of the second module.

20. The apparatus of claim 18, wherein the apparatus is part of a personal computer, a server, a mobile device, a tablet, or an automobile.
